(19) United States
(12) Patent Application Publication
(10) Pub. No.: US 2015/0228717 A1
(43) Pub. Date: Aug. 13, 2015

(54) METHOD FOR MANUFACTURING SEMICONDUCTOR DEVICE AND SEMICONDUCTOR DEVICE

(71) Applicant: Masafumi Hara, Miyoshi-shi Aichi-ken (JP)

(72) Inventor: Masafumi Hara, Miyoshi-shi Aichi-ken (JP)

(73) Assignee: TOYOTA JIDOSHA KABUSHIKI KAISHA, Toyota-shi Aichi-ken (JP)

(21) Appl. No.: 14/607,604

(22) Filed: Jan. 28, 2015

(30) Foreign Application Priority Data
Feb. 10, 2014 (JP) 2014-023864

(51) Int. Cl. H01L 29/06; H01L 29/739; H01L 29/66; H01L 27/06

(52) U.S. Cl. CPC H01L 29/0626; H01L 27/0635; H01L 29/0696; H01L 29/7397; H01L 29/66348

(57) ABSTRACT

A semiconductor device having high durability against avalanche breakdown is provided. A method for manufacturing a semiconductor device is provided with an IGBT region, a diode region, and a peripheral region includes: forming crystal defects in an n-type region by implanting charged particles into an n-type region in the diode region and an n-type region in the peripheral region; and forming crystal defects in the n-type region by implanting charged particles into an n-type region in the IGBT region and the n-type region in the peripheral region.

### CROSS-REFERENCE TO RELATED APPLICATION

This application claims priority to Japanese Patent Application No. 2014-023864 filed on Feb. 10, 2014, the contents of which are hereby incorporated by reference into the present application.

### TECHNICAL FIELD

A technology disclosed in this description relates to a semiconductor device.

### DESCRIPTION OF RELATED ART

Japanese Patent Application Publication No. 2011-129619 discloses a semiconductor device in which an IGBT and a diode are integrated. Crystal defects formed by implanting charged particles are present in a drift region of the IGBT and a drift region of the diode. Such crystal defects function as recombination centers of carriers. While the diode is on, a part of holes having flowed into the drift region of the diode disappears in the crystal defects. As a result, a rise of concentration of the holes in the drift region of the diode is suppressed, and a recovery characteristic of the diode is improved. While the IGBT is on, a part of the holes having flowed into the drift region of the IGBT disappears in the crystal defects. As a result, a rise of concentration of the holes in the drift region of the IGBT is suppressed, and a switching characteristic of the IGBT is improved.

If crystal defects are formed in the IGBT region and the diode region, electric resistance of the drift region rises in the IGBT region and the diode region. As a result, UIS durability (index of ease of occurrence of avalanche breakdown) of the IGBT region and the diode region becomes higher than that in their peripheral regions (regions on outer sides of the IGBT region and the diode region). Thus, when an overvoltage is applied, avalanche breakdown can easily occur in the peripheral region. Since there are fewer current paths in the peripheral region, durability against avalanche breakdown is low in the peripheral region. Thus, if avalanche breakdown can easily occur in the peripheral region as described above, there is a problem that durability against avalanche breakdown as the entire semiconductor device drops.

### BRIEF SUMMARY

With a manufacturing method disclosed in this specification according to one aspect, manufactured is a semiconductor device comprising a semiconductor substrate, a front surface electrode formed on a front surface of the semiconductor substrate and a rear surface electrode formed on a rear surface of the semiconductor substrate. The semiconductor substrate comprises an IGBT region, a diode region, and a peripheral region. An n-type region is formed across the IGBT region, the diode region, and the peripheral region. The IGBT region comprises: an n-type emitter region connected to the front surface electrode; a p-type body region connected to the front surface electrode; the n-type region separated from the emitter region by the body region; a p-type collector region separated from the body region by the n-type region, and connected to the rear surface electrode; a gate insulating film being in contact with the body region; and a gate electrode facing the body region via the gate insulating film. The diode region comprises: a p-type anode region connected to the front surface electrode; and the n-type region connected to the rear surface electrode. The manufacturing method comprises: forming crystal defects in the n-type region by implanting charged particles into the n-type region in the diode region and the n-type region in the peripheral region; and forming crystal defects in the n-type region by implanting charged particles into the n-type region in the IGBT region and the n-type region in the peripheral region.

In this method for manufacturing, when the crystal defects are formed in the n-type region in the diode region, the crystal defects are formed also in the n-type region in the peripheral region. Moreover, when the crystal defects are formed in the n-type region in the IGBT region, the crystal defects are formed also in the n-type region in the peripheral region. Therefore, in the n-type region in the peripheral region, the crystal defects are formed with a density higher than that in the n-type region in the IGBT region and in the n-type region in the diode region. Thus, in the semiconductor device manufactured by this method, avalanche breakdown can occur more easily in the IGBT region and the diode region than in the peripheral region. Therefore, the semiconductor device manufactured by this method has high durability against avalanche breakdown.

In another aspect, the present specification provides a new semiconductor device. This semiconductor device comprises a semiconductor substrate, a front surface electrode formed on a front surface of the semiconductor substrate, and a rear surface electrode formed on a rear surface of the semiconductor substrate. The semiconductor substrate comprises an IGBT region, a diode region, and a peripheral region. An n-type region is formed across the IGBT region, the diode region, and the peripheral region. The IGBT region comprises: an n-type emitter region connected to the front surface electrode; a p-type body region connected to the front surface electrode; the n-type region separated from the emitter region by the body region; a p-type collector region separated from the body region by the n-type region, and connected to the rear surface electrode; a gate insulating film being in contact with the body region; and a gate electrode facing the body region via the gate insulating film. The diode region comprises: a p-type anode region connected to the front surface electrode; and the n-type region connected to the rear surface electrode. An average density of crystal defects in the n-type region in the peripheral region is larger than an average density of crystal defects in the n-type region in the IGBT region, and is larger than an average density of crystal defects in the n-type region in the diode region.

### BRIEF DESCRIPTION OF DRAWINGS

FIG. 1 shows a longitudinal sectional view of a semiconductor device 10;

FIG. 2 is a graph showing distribution of a crystal defect density in a drift region 26 in a peripheral region 60;

FIG. 3 is a diagram showing implanting of charged particles into lifetime control regions 70 and 74; and

FIG. 4 is a view showing implanting of the charged particles into lifetime control regions 72 and 76.

FIG. 5 shows a longitudinal sectional view of a semiconductor device of another embodiment.

### DETAILED DESCRIPTION

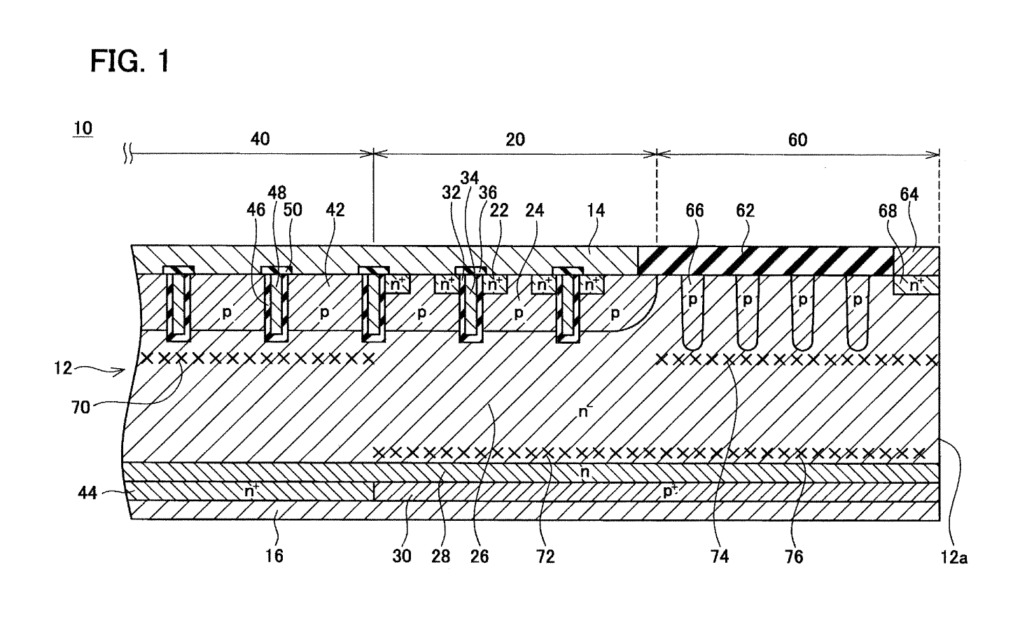

A semiconductor device 10 of an embodiment illustrated in FIG. 1 comprises a semiconductor substrate 12, a front surface electrode 14 formed on a front surface of the semiconductor substrate 12, and a rear surface electrode 16 formed on a rear surface of the semiconductor substrate 12. The semiconductor substrate 12 is a substrate made of silicon.

The semiconductor substrate 12 comprises an IGBT region 20 in which a vertical-type IGBT is formed, a diode region 40 in which a vertical-type diode is formed, and a peripheral region 60 on an outer side of the IGBT region 20 and the diode region 40. The peripheral region 60 is formed between the IGBT region 20 and an end face 12a of the semiconductor substrate 12. Alternatively, the peripheral region 60 may be formed between the diode region 40 and the end surface 12a of the semiconductor substrate 12.

An emitter region 22, a body region 24, a drift region 26, a buffer region 28, and a collector region 30 are formed in the semiconductor substrate 12 in the IGBT region 20.

The emitter region 22 is an n-type region and is formed in an area exposed in an upper surface of the semiconductor substrate 12. The emitter region 22 is ohmically connected to the front surface electrode 14.

The body region 24 is a p-type region and is formed in an area exposed in the upper surface of the semiconductor substrate 12. The body region 24 extends from a side of the emitter region 22 to a lower side of the emitter region 22. The body region 24 is ohmically connected to the front surface electrode 14.

The drift region 26 is an n-type region and is formed on a lower side of the body region 24. The drift region 26 is separated from the emitter region 22 by the body region 24. N-type impurity concentration in the drift region 26 is low.

The buffer region 28 is an n-type region and is formed on a lower side of the drift region 26. N-type impurity concentration in the buffer region 28 is higher than that in the drift region 26.

The collector region 30 is a p-type region and is formed on a lower side of the buffer region 28. The collector region 30 is formed in an area exposed in a lower surface of the semiconductor substrate 12. The collector region 30 is ohmically connected to the rear surface electrode 16. The collector region 30 is separated from the body region 24 by the drift region 26 and the buffer region 28.

A plurality of trenches are formed on the upper surface of the semiconductor substrate 12 in the IGBT region 20. Each of the trenches is formed at a position adjacent to the emitter region 22. Each of the trenches extends to a depth reaching the drift region 26.

An inner surface of each of the trenches in the IGBT region 20 is covered by a gate insulating film 32. In each of the trenches, a gate electrode 34 is arranged. Each of the gate electrodes 34 is insulated from the semiconductor substrate 12 by the gate insulating film 32. Each of the gate electrodes 34 is faced with the emitter region 22, the body region 24, and the drift region 26 through the gate insulating film 32. On each of the gate electrodes 34, an insulating film 36 is formed. Each of the gate electrodes 34 is insulated from the front surface electrode 14 by the insulating film 36.

In the semiconductor substrate 12 in the diode region 40, an anode region 42, the drift region 26, the buffer region 28, and a cathode region 44 are formed.

The anode region 42 is formed in an area exposed in the upper surface of the semiconductor substrate 12. The anode region 42 is ohmically connected to the front surface electrode 14.

On a lower side of the anode region 42, the above-described drift region 26 is formed. The drift region 26 in the diode region 40 is connected with the drift region 26 in the IGBT region 20. That is, the drift region 26 continuously extends into the diode region 40 from an inside of the IGBT region 20.

On the lower side of the drift region 26 in the diode region 40, the above-described buffer region 28 is formed. That is, the buffer region 28 continuously extends into the diode region 40 from the inside of the IGBT region 20.

The cathode region 44 is an n-type region and is formed on the lower side of the buffer region 28 in the diode region 40. The cathode region 44 is formed in an area exposed in the lower surface of the semiconductor substrate 12. The cathode region 44 has the n-type impurity concentration higher than that in the buffer region 28. The cathode region 44 is ohmically connected to the rear surface electrode 16.

A plurality of trenches are formed on the upper surface of the semiconductor substrate 12 in the diode region 40. Each of the trenches extends to the depth reaching the drift region 26.

An inner surface of each of the trenches in the diode region 40 is covered by an insulating film 46. In addition, a control electrode 48 is arranged in each of the trenches. Each of the control electrodes 48 is insulated from the semiconductor substrate 12 by the insulating film 46. Each of the control electrodes 48 is faced with the anode region 42 and the drift region 26 through the insulating film 46. An insulating film 50 is formed on an upper part of each of the control electrodes 48. Each of the control electrodes 48 is insulated from the front surface electrode 14 by the insulating film 50.

On the front surface of the semiconductor substrate 12 in the peripheral region 60, a peripheral electrode 64 and an insulating layer 62 are formed. The peripheral electrode 64 is formed along the end surface 12a of the semiconductor substrate 12. The insulating layer 62 covers most of the semiconductor substrate 12 in the peripheral region 60. On the rear surface of the semiconductor substrate 12 in the peripheral region 60, the above-described rear surface electrode 16 is formed. In the semiconductor substrate 12 in the peripheral region 60, the drift region 26, the buffer region 28, the collector region 30, a guard ring 66, and a terminal n-type region 68 are formed.

The drift region 26 in the peripheral region 60 is connected with the drift region 26 in the IGBT region 20. That is, the drift region 26 continuously extends into the peripheral region 60 from the inside of the IGBT region 20.

On the lower side of the drift region 26 in the peripheral region 60, the above-described buffer region 28 is formed. That is, the buffer region 28 continuously extends into the peripheral region 60 from the inside of the IGBT region 20.

On the lower side of the buffer region 28 in the peripheral region 60, the above-described collector region 30 is formed. That is, the collector region 30 continuously extends into the peripheral region 60 from the inside of the IGBT region 20. In the peripheral region 60, the collector region 30 is also ohmically connected to the rear surface electrode 16.

The guard rings 66 are p-type regions and are formed in plural in the peripheral region 60. Each of the guard rings 66 is formed in an area exposed in the front surface of the semiconductor substrate 12. The drift region 26 is formed between each of the guard rings 66. Each of the guard rings 66 is separated from each other by the drift region 26. Each of the guard rings 66 is formed so as to go round the peripheries of the IGBT region 20 and the diode region 40 when the front surface of the semiconductor substrate 12 is seen. The guard ring 66 extends from the front surface of the semiconductor substrate 12 to a position deeper than lower ends of the gate electrodes 34 and the control electrodes 48.

The terminal n-type region 68 is formed in an area exposed in the end surface 12a and the front surface of the semiconductor substrate 12. The terminal n-type region 68 has the n-type impurity concentration higher than that in the drift region 26. The terminal n-type region 68 is ohmically connected to the peripheral electrode 64.

As explained above, in the semiconductor substrate 12, an n-type region (that is, a continuous n-type region including the drift region 26, the buffer region 28, and the cathode region 44) is formed extending across the IGBT region 20, the diode region 40, and the peripheral region 60.

In the drift region 26, a lifetime control region with a crystal defect density higher than that of the periphery is formed. A depth to which the lifetime control region is formed is different among the IGBT region 20, the diode region 40, and the peripheral region 60.

In the drift region 26 in the IGBT region 20, a first lifetime control region 72 is formed. The first lifetime control region 72 is formed in a region on the rear surface side in the drift region 26 (that is, a region closer to the rear surface side than a center of the drift region 26 in a depth direction). In more detail, the first lifetime control region 72 is formed in the vicinity of the buffer region 28. The first lifetime control region 72 is formed in substantially the entire region in a width direction of the IGBT region 20 (a direction in parallel with the front surface of the semiconductor substrate 12).

In the drift region 26 in the diode region 40, a second lifetime control region 70 is formed. The second lifetime control region 70 is formed in a region on a front surface side in the drift region 26 (that is, a region closer to the front surface side than the center of the drift region 26 in the depth direction). In more detail, the second lifetime control region 70 is formed in the vicinity of the anode region 42. The second lifetime control region 70 is formed in substantially the entire region in the width direction of the diode region 40 (the direction in parallel with the front surface of the semiconductor substrate 12).

In the drift region 26 in the peripheral region 60, a third lifetime control region 76 and a fourth lifetime control region 74 are formed. The third lifetime control region 76 is formed at substantially the same depth as the first lifetime control region 72 (that is, in the vicinity of the buffer region 28). The fourth lifetime control region 74 is formed at substantially the same depth as the second lifetime control region 70 (that is, at the depth in the vicinity of a lower end of the guard ring 66). The third lifetime control region 76 and the fourth lifetime control region 74 are formed on substantially the entire region in the width direction of the peripheral region 60 (the direction in parallel with the front surface of the semiconductor substrate 12).

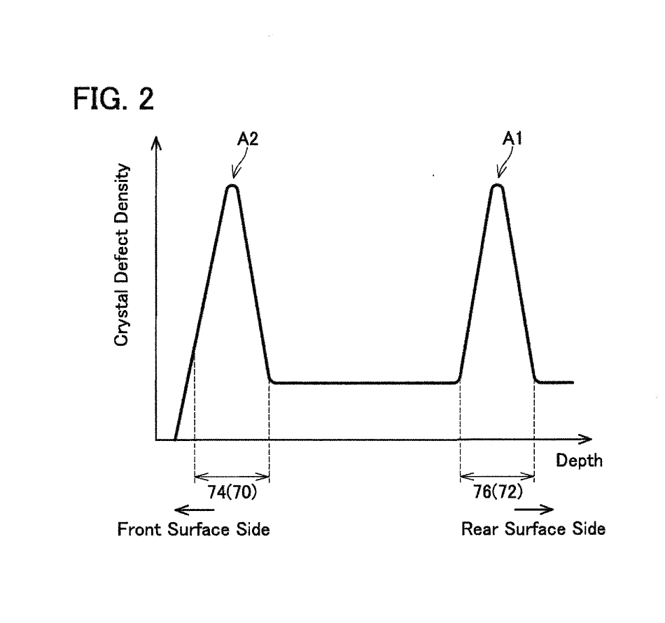

As illustrated in FIG. 2, in the third lifetime control region 76, a first peak A1 of the crystal defect density is formed. In the fourth lifetime control region 74, a second peak A2 of the crystal defect density is formed. As described above, the first lifetime control region 72 is formed at substantially the same depth as the third lifetime control region 76. In the third lifetime control region 76, too, the first peak A1 of the crystal defect density is formed. In the drift region 26 in the IGBT region 20, the second peak A2 is not formed. Moreover, as described above, the second lifetime control region 70 is formed at substantially the same depth as the fourth lifetime control region 74. In the second lifetime control region 70, too, the second peak A2 of the crystal defect density is formed. In the drift region 26 in the diode region 40, the first peak A1 is not formed. Either of the first peak A1 and the second peak A2 may be larger. As described above, since two peaks A1 and A2 are formed in the drift region 26 in the peripheral region 60, an average crystal defect density of the drift region 26 in the peripheral region 60 is higher than the average crystal defect densities of the IGBT region 20 and the diode region 40. The crystal defects in each of the lifetime control regions scatter carriers and raise electric resistance of the drift region 26. In the peripheral region 60, since the average crystal defect density is higher than the IGBT region 20 and the diode region 40, the electric resistance is larger than the IGBT region 20 and the diode region 40. That is, electric resistance between an upper end and a lower end of the n-type region (the drift region 26 and the buffer region 28) in the peripheral region 60 is higher than the electric resistance between the upper end and the lower end of the n-type region (the drift region 26 and the buffer region 28) in the IGBT region 20 and is larger than the electric resistance between the upper end and the lower end of the n-type region (the drift region 26, the buffer region 28, and the cathode region 44) in the diode region 40.

When a voltage causing the front surface electrode 14 to be positive is applied between the front surface electrode 14 and the rear surface electrode 16, the diode in the diode region 40 is turned on. That is, an electric current flows from the anode region 42 into the cathode region 44 via the drift region 26 and the buffer region 28. At this time, in the second lifetime control region 70, holes having flowed from the anode region 42 into the drift region 26 disappear by recombination. As a result, a rise of a hole density in the drift region 26 is suppressed. Since the second lifetime control region 70 is formed at a position close to the anode region 42 (that is, on the front surface side), the holes flowing from the anode region 42 to the drift region 26 can be made to disappear effectively by recombination. As a result, the rise of the hole density in the drift region 26 is suppressed more effectively. After that, when the voltage between the front surface electrode 14 and the rear surface electrode 16 is switched to a reverse voltage (voltage causing the rear surface electrode 16 to be positive), the diode performs recovery operation. That is, since the holes present in the drift region 26 is discharged to the front surface electrode 14, a reverse current temporarily flows in the diode. In this semiconductor device 10, since a quantity of the holes present in the drift region 26 is small while the diode is on, the quantity of the holes discharged to the front surface electrode 14 during the recovery operation is also small. Thus, the reverse current flowing in the recovery operation is small.

When a voltage causing the rear surface electrode 16 to be positive is applied between the front surface electrode 14 and the rear surface electrode 16 and a voltage at a threshold value or more (hereinafter referred to as a gate-on voltage) is applied to the gate electrode 34, the IGBT in the IGBT region 20 is turned on. That is, a channel is formed in the body region 24 in an area in contact with the gate insulating film 32. As a result, electrons flow from the emitter region 22 via the channel, the drift region 26, and the buffer region 28 to the collector region 30. Moreover, the holes flow from the collector region 30 via the drift region 26 to the body region 24. Therefore, a current flows from the rear surface electrode 16 toward the front surface electrode 14. At this time, in the first lifetime control region 72, the holes having flowed from the collector region 30 into the drift region 26 disappear by recombination. As a result, a rise of the hole concentration in the drift region 26 is suppressed. Since the first lifetime control region 72 is formed at a position close to the collector region 30 (that is, on the rear surface side), the holes flowing from the collector region 30 into the drift region 26 can be effectively made to disappear by recombination. As a result, the rise of the hole concentration in the drift region 26 can be effectively suppressed. After that, if application of the gate-on voltage is stopped, the channel is lost, and the IGBT is turned off. At this time, the holes present in the drift region 26 are discharged to the front surface electrode 14. As a result, even after the channel is lost, the current temporarily flows through the IGBT. However, in this semiconductor device 10, since there are few holes present in the drift region 26 while the IGBT is on, few holes are discharged to the front surface electrode 14 after the channel is lost. Thus, the current flowing after the channel is lost is small.

Moreover, if an overvoltage is applied between the front surface electrode 14 and the rear surface electrode 16, avalanche breakdown might occur in the semiconductor substrate 12. Here, as described above, the electric resistance of the n-type region in the peripheral region 60 is larger than the electric resistance of the n-type region in the IGBT region 20 and the diode region 40. Therefore, the peripheral region 60 has higher UIS durability than that in the IGBT region 20 and the diode region 40. Thus, if the overvoltage is applied between the front surface electrode 14 and the rear surface electrode 16, avalanche breakdown occurs in the IGBT region 20 or in the diode region 40, and avalanche breakdown does not occur in the peripheral region 60. Since the IGBT region 20 and the diode region 40 (that is, active regions) have wide current paths, even if holes are generated by avalanche breakdown, the holes can be easily diffused. Thus, in the IGBT region 20 and the diode region 40, durability against avalanche breakdown is high. By causing avalanche breakdown in the IGBT region 20 and the diode region 40 with high durability as above, durability of the entire semiconductor device 10 can be improved.

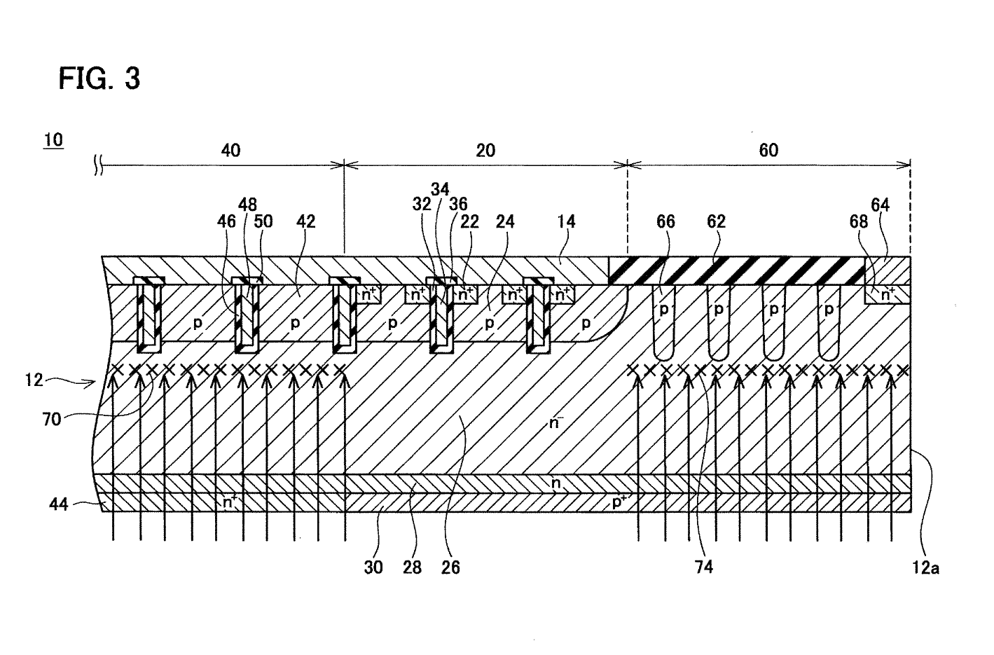

A method for manufacturing the semiconductor device 10 will be explained. First, as illustrated in FIG. 3, a structure of the semiconductor device 10 other than the rear surface electrode 16 is formed in the semiconductor substrate 12. Subsequently, as illustrated in FIG. 3, charged particles (helium ions or protons, for example) are implanted toward the rear surface of the semiconductor substrate 12. At this time, the IGBT region 20 is covered by a mask so that the charged particles are not implanted into the IGBT region 20. Therefore, the charged particles are implanted into the diode region 40 and the peripheral region 60. Moreover, at this time, irradiation energy of the charged particles is adjusted so that an average stop position of the implanted charged particles is in the drift region 26 on the front surface side. The charged particles implanted into the semiconductor substrate 12 form crystal defects in the semiconductor substrate 12 when advancing through the semiconductor substrate 12. Particularly, the charged particles form many crystal defects in the vicinity of the stop position. Therefore, the peak A2 of the crystal defect density is formed in the drift region 26 on the front surface side. That is, the second lifetime control region 70 is formed in the diode region 40, and the fourth lifetime control region 74 is formed in the peripheral region 60.

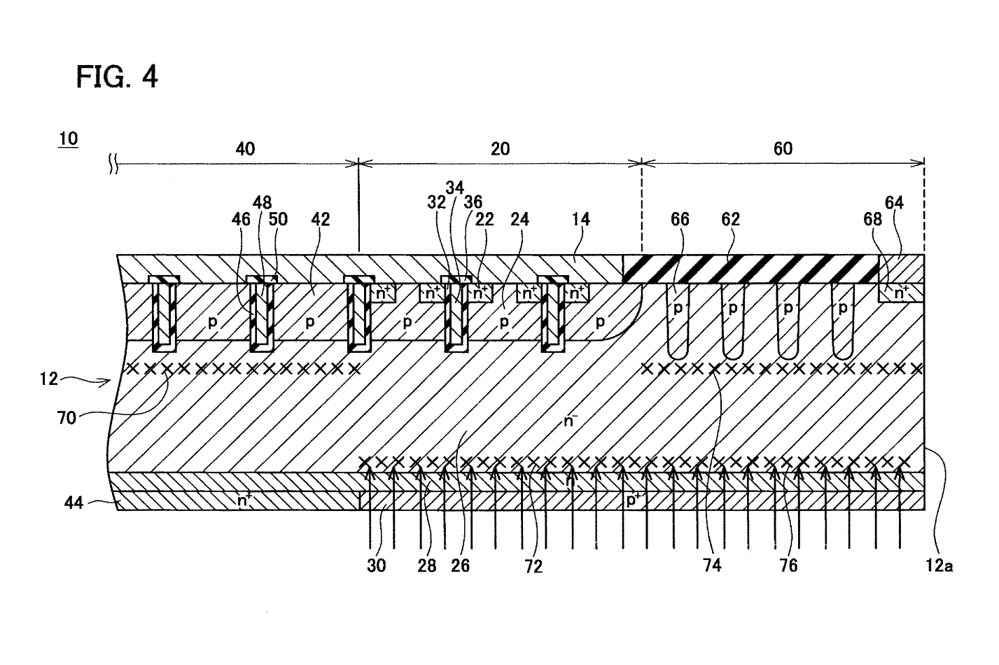

Subsequently, as illustrated in FIG. 4, the charged particles (helium ions or protons, for example) are implanted toward the rear surface of the semiconductor substrate 12. At this time, the diode region 40 is covered by a mask so that the charged particles are not implanted into the diode region 40. Therefore, the charged particles are implanted into the IGBT region 20 and the peripheral region 60. Moreover, at this time, the irradiation energy of the charged particles is adjusted so that the average stop position of the implanted charged particles is in the drift region 26 on the rear surface side. The charged particles implanted into the semiconductor 12 form crystal defects in the semiconductor substrate 12 when advancing through the semiconductor substrate 12. Particularly, the charged particles form many crystal defects in the vicinity of the stop position. Therefore, the peak A1 of the crystal defect density is formed in the drift region 26 on the rear surface side. That is, the first lifetime control region 72 is formed in the IGBT region 20, and the third lifetime control region 76 is formed in the peripheral region 60. After that, by forming the rear surface electrode 16, the semiconductor device 10 is completed.

As explained above, in this method of manufacturing, when the charged particles are implanted into the IGBT region 20, the charged particles are implanted also into the peripheral region 60, and when the charged particles are implanted into the diode region 40, the charged particles are implanted also into the peripheral region 60. Therefore, the average crystal defect density becomes the highest in the peripheral region 60. Thus, when an overvoltage is applied, avalanche breakdown can be caused in the IGBT region 20 or in the diode region 40.

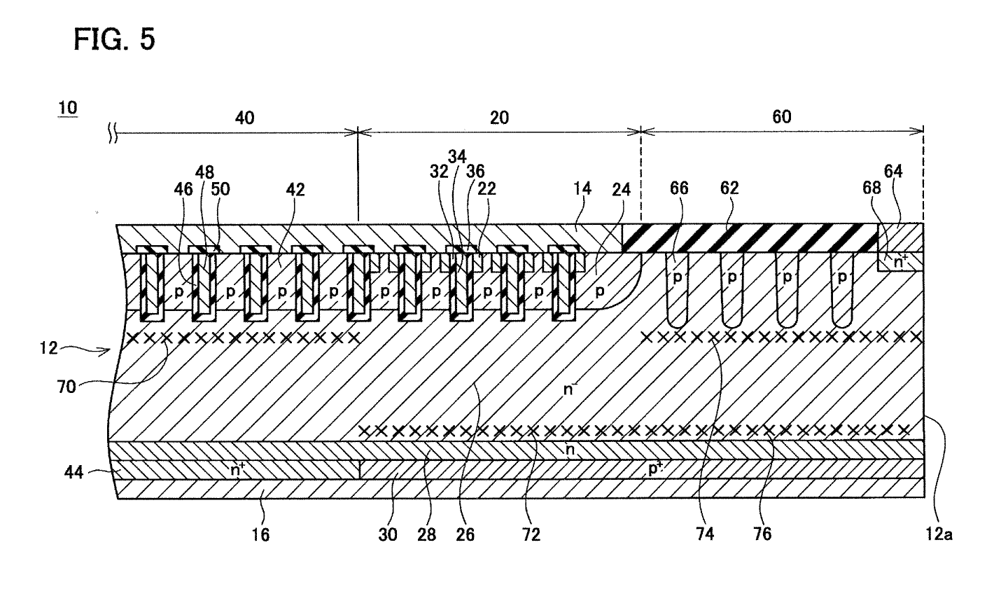

As explained above, according to the technology of this embodiment, since avalanche breakdown becomes difficult to be caused in the peripheral region 60, durability against avalanche breakdown of the semiconductor device 10 can be improved. Since avalanche breakdown becomes difficult to be caused in the peripheral region 60 as above, as illustrated in FIG. 5, a pitch of the gate trenches in the IGBT region 20 may be made smaller. By making the pitch of the gate trenches smaller, a channel density is raised, and an ON loss of the IGBT can be reduced. Moreover, if the pitch of the gate trenches is made smaller as above, the UIS durability of the IGBT region 20 is raised. The UIS durability of the IGBT region 20 needs to be lower than the UIS durability of the peripheral region 60, but if the UIS durability of the peripheral region 60 is improved as above, the UIS durability of the IGBT region 20 can be also improved. Therefore, by making the pitch of the gate trenches smaller within a range in which the UIS durability of the IGBT region 20 is lower than the UIS durability of the peripheral region 60, characteristics of the IGBT can be improved. Moreover, as illustrated in FIG. 5, the pitch of the trenches in the diode region 40 may be made smaller.

In the method for manufacturing of the above-described embodiment, the charged particles are implanted into the semiconductor substrate 12 from the rear surface as illustrated in FIGS. 3 and 4. However, instead of above mentioned implanting of the charged particles, the charged particles may be implanted into the semiconductor substrate 12 from the front surface. Moreover, implanting of the charged particles into the first lifetime control region 72 and the third lifetime control region 76 may be performed prior to implanting of the charged particles into the second lifetime control region 70 and the fourth lifetime control region 74.

When the charged particles are to be implanted, crystal defects are formed with a low density also in a passage path of the charged particles. Thus, when the charged particles are to be implanted from the rear surface as illustrated in FIG. 3, for example, the crystal defects are formed with a low density also in the drift region 26 on a lower side of the lifetime control regions 70 and 74. Moreover, if the lifetime control regions 72 and 76 are to be formed by implanting the charged particles from the front surface, the crystal defects with a low density are formed also in the drift region 26 on an upper side of the lifetime control regions 72 and 76. If such crystal defects with a low density are not to be formed, an implanting process of the charged particles from the front surface and an implanting process of the charged particles from the rear surface may be performed in combination.

Moreover, in the above-described embodiment, the first lifetime control region 72 and the third lifetime control region 76 are formed in the drift region 26, but these lifetime control regions may be formed in the buffer region 28.

Some of the features of the technique disclosed above may be listed. In the above-described manufacturing method, it is preferable that a peak of density of the crystal defects is formed in a region located in the n-type region on a front surface side by the implanting of the charged particles into the n-type region in the diode region and the n-type region in the peripheral region, and a peak of density of the crystal defects is formed in a region located in the n-type region on a rear surface side by the implanting of the charged particles into the n-type region in the IGBT region and the n-type region in the peripheral region.

According to the above-described configuration, a recovery characteristic of the diode and a switching characteristic of the IGBT can be improved.

In the above-described manufacturing method, it is preferable that an electric resistance of the n-type region between an end portion of the n-type region on a front surface side and an end portion of the n-type region on a rear surface side is larger in the peripheral region than in the IGBT region, and is larger in the peripheral region than in the diode region.

In the above-described semiconductor device, the n-type region in the IGBT region may have a peak of a density of the crystal defects in a region on a front surface side, and the n-type region in the diode region may have a peak of a density of the crystal defects in a region on a rear surface side.

Furthermore, in the above-described semiconductor device, an electric resistance of the n-type region between an end portion of the n-type region on a front surface side and an end portion of the n-type region on a rear surface side may be larger in the peripheral region than in the IGBT region, and may be larger in the peripheral region than in the diode region.

According to the above-described configurations of the semiconductor device, durability against avalanche breakdown can be improved.

The specific examples of the present invention were explained in detail as above, but these are only exemplification and are not intended to limit the claims. The technology described in the claims includes various variations and changes of the specific examples exemplified above.

The technical elements explained in this description or the drawings exert technical usability singularly or in various combinations and are not intended to be limited to the combination described in the claims at filing. Moreover, the technology exemplified in this description or the drawings is to achieve a plurality of objects at the same time, and achievement of one of them itself has technical usability.

1. A method for manufacturing a semiconductor device, wherein
the semiconductor device comprises a semiconductor substrate, a front surface electrode formed on a front surface of the semiconductor substrate, and a rear surface electrode formed on a rear surface of the semiconductor substrate,
the semiconductor substrate comprises an IGBT region, a diode region, and a peripheral region,
an n-type region is formed across the IGBT region, the diode region, and the peripheral region,
the IGBT region comprises:
an n-type emitter region connected to the front surface electrode;
a p-type body region connected to the front surface electrode;
the n-type region separated from the emitter region by the body region;
a p-type collector region separated from the body region by the n-type region, and connected to the rear surface electrode;
a gate insulating film being in contact with the body region; and
a gate electrode facing the body region via the gate insulating film,
the diode region comprises:
a p-type anode region connected to the front surface electrode; and
the n-type region connected to the rear surface electrode,
the method comprises:
forming crystal defects in the n-type region by implanting charged particles into the n-type region in the diode region and the n-type region in the peripheral region; and
forming crystal defects in the n-type region by implanting charged particles into the n-type region in the IGBT region and the n-type region in the peripheral region.

2. A method of claim 1, wherein
a peak of density of the crystal defects is formed in a region located in the n-type region on a front surface side by the implanting of the charged particles into the n-type region in the diode region and the n-type region in the peripheral region; and
a peak of density of the crystal defects is formed in a region located in the n-type region on a rear surface side by the implanting of the charged particles into the n-type region in the IGBT region and the n-type region in the peripheral region.

3. A method of claim 1, wherein
an electric resistance of the n-type region between an end portion of the n-type region on a front surface side and an end portion of the n-type region on a rear surface side is larger in the peripheral region than in the IGBT region, and is larger in the peripheral region than in the diode region.

4. A semiconductor device comprising a semiconductor substrate, a front surface electrode formed on a front surface of the semiconductor substrate, and a rear surface electrode formed on a rear surface of the semiconductor substrate, wherein
the semiconductor substrate comprises an IGBT region, a diode region, and a peripheral region,
an n-type region is formed across the IGBT region, the diode region, and the peripheral region,
the IGBT region comprises:
an n-type emitter region connected to the front surface electrode;
a p-type body region connected to the front surface electrode;
the n-type region separated from the emitter region by the body region;
a p-type collector region separated from the body region by the n-type region, and connected to the rear surface electrode;
a gate insulating film being in contact with the body region; and
a gate electrode facing the body region via the gate insulating film,
the diode region comprises:
a p-type anode region connected to the front surface electrode; and
the n-type region connected to the rear surface electrode, and
an average density of crystal defects in the n-type region in the peripheral region is larger than an average density of crystal defects in the n-type region in the IGBT region, and is larger than an average density of crystal defects in the n-type region in the diode region.

5. A semiconductor device of claim 4, wherein
the n-type region in the IGBT region has a peak of a density of the crystal defects in a region on a front surface side, and
the n-type region in the diode region has a peak of a density of the crystal defects in a region on a rear surface side.

6. A semiconductor device of claim 4, wherein
an electric resistance of the n-type region between an end portion of the n-type region on a front surface side and an end portion of the n-type region on a rear surface side is larger in the peripheral region than in the IGBT region, and is larger in the peripheral region than in the diode region.
